(19) United States
(12) Patent Application Publication
(10) Pub. No.: US 2012/0069528 A1
(43) Pub. Date: Mar. 22, 2012

(54) Method for Control of Solder Collapse in Stacked Microelectronic Structure

(75) Inventors: Randy Bindrup, Trabucco Canyon, CA (US); James Yamaguchi, Laguna Niguel, CA (US); W. Eric Boyd, La Mesa, CA (US)

(73) Assignee: Irvine Sensors Corporation, Costa Mesa, CA (US)

(21) Appl. No.: 13/209,933

(22) Filed: Aug. 15, 2011

Related U.S. Application Data
(60) Provisional application No. 61/403,517, filed on Sep. 17, 2010.

(51) Int. Cl. H05K 7/00; B23K 1/20

(52) U.S. Cl. 361/728; 228/256

(57) ABSTRACT

A process and product made from the process is disclosed to minimize solder collapse during solder reflow.

Predetermined bond pads on a layer or component have a solder paste such as Sn63 solder paste with a first lower reflow temperature applied and a spacer element such as an SAC solder ball or stud bump having a predetermined geometry with a second higher reflow temperature applied. The SAC solder balls or stud bumps act as spacing elements but do not interact with the solder paste such that the solder paste may be reflowed while precisely maintaining the space between the layers.

### CROSS-REFERENCE TO RELATED APPLICATIONS

This application claims the benefit of U.S. Provisional Patent Application No. 61/403,517, filed on Sep. 17, 2010 entitled “Control of Solder Collapse in Massive Structures” pursuant to 35 USC 119, which application is incorporated fully herein by reference.

### STATEMENT REGARDING FEDERALLY SPONSORED RESEARCH AND DEVELOPMENT

N/A

### BACKGROUND OF THE INVENTION

1. Field of the Invention

The invention relates generally to the field of solder materials and methods used in electronics.

More specifically, the invention relates to a method for preventing solder collapse in stacked, multilayer microelectronic structures during solder reflow operations by reducing the total number of solder reflow steps by exploiting different reflow temperatures of different solder materials.

2. Description of the Related Art

The ability to fabricate very thin, stackable layers, containing one or a plurality of homogeneous or heterogeneous integrated circuit chips is desirable and allows high density, high speed electronic systems to be assembled for use in military, space, security and other applications.

Examples of such layers and modules are disclosed in U.S. Pat. No. 6,797,537, Method of Making Stackable Layers Containing Encapsulated Integrated Circuit Chips With One or More Overlying Interconnect Layers, U.S. Pat. No. 6,784,547, Stackable Layers Containing Encapsulated Integrated Circuit Chips With One or More Overlying Interconnect Layers, U.S. Pat. No. 6,117,704, Stackable Layer Containing Encapsulated Chips, U.S. Pat. No. 6,072,234, Stack of Equal Layer Neo-Chips Containing Encapsulated IC Chips of Different Sizes, and U.S. Pat. No. 5,953,588, Stackable Layers Containing Encapsulated IC Chips, and U.S. Pat. No. 7,768,113 issued Aug. 3, 2010 entitled “Stackable Tier Structure Comprising Prefabricated High Density Feed-through” to Ozguz et al.

The stacking and interconnection of very thin microelectronic layers allows high circuit speeds in part because of short lead lengths and related reduced parasitic impedance and electron time-of-flight. These desirable features combined with a very high number of circuit and layer interconnections allows relatively large I/O designs to be implemented in a small volume. What is needed is a structure that combines the above attributes but that can be fabricated using well-defined processes at relatively low cost.

One challenge to be overcome in fabricating multilayer electronic modules in certain applications is a process problem referred to herein as “solder collapse”. Solder collapse occurs when solder elements such as solder balls which may be disposed in the form of a solder ball grid array (BGA) between layers in a microelectronic module are reflowed. During reflow, the layers compress upon themselves due to the melting of the solder balls disposed between the layers which can result in misalignment or shorting of the electrical contact pads between the layers.

A process is needed to minimize or eliminate solder collapse during fabrication of multilayer modules during reflow processes.

### BRIEF SUMMARY OF THE INVENTION

A process and product made from the process is disclosed to minimize solder collapse during solder reflow.

In a first aspect of the invention, the process may comprise the steps of providing a first layer having a first surface having first bond location disposed on it, disposing a solder paste having a first lower reflow temperature and a spacer element on the first bond pad and reflowing the solder paste at the first lower reflow temperature.

In a second aspect of the invention, the spacer element may be an SAC solder ball having a predetermined geometry.

In a third aspect of the invention, the spacer element may have a higher reflow temperature than the solder paste to define a second higher reflow temperature.

In a fourth aspect of the invention, the spacer element may be comprised of at least one stud bump defined by a wire bond machine.

In a fifth aspect of the invention, the process may comprise providing a first layer having a first surface having first bond location disposed on it, providing a second layer having a second surface having a second bond location disposed on it, disposing a solder paste having a first lower reflow temperature and a spacer element between the first bond pad and the second bond pad, aligning the first layer with the second layer whereby the first bond pad and the second bond pad are in physical communication with the solder paste and reflowing the solder paste at the first lower reflow temperature.

In a sixth aspect of the invention, the spacer element between the layers may be an SAC solder ball having a predetermined geometry.

In a seventh aspect of the invention, the spacer element between the layers may have a higher reflow temperature than the solder paste to define a second higher reflow temperature.

In an eighth aspect of the invention, the spacer element may define a predetermined distance between the first bond pad and the second bond pad.

In a ninth aspect of the invention, the spacer element comprises at least one stud bump defined by a wire bond machine.

In a tenth aspect of the invention an electronic module is disclosed that is prepared by a process comprising the steps of providing a first layer having a first surface having a first bond location disposed it, providing a second layer having a second surface having a second bond location disposed thereon, disposing a solder paste having a first lower reflow temperature and a spacer element between the first bond pad and the second bond pad, aligning the first layer with the second layer whereby the first bond pad and the second bond pad are in physical communication with the solder paste and reflowing the solder paste at the first lower reflow temperature.

In an eleventh aspect of the invention, the spacer element in the module may be an SAC solder ball having a predetermined geometry.

In a twelfth aspect of the invention, the spacer element of the module may have a higher reflow temperature than the solder paste to define a second higher reflow temperature.

In a thirteenth aspect of the invention, the spacer element of the module may define a predetermined distance between the first bond pad and the second bond pad.

In a fourteenth aspect of the invention, the spacer element of the module may comprise at least one stud bump defined by a wire bond machine.

These and various additional aspects, embodiments and advantages of the present invention will become immediately apparent to those of ordinary skill in the art upon review of the Detailed Description and any claims to follow.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE SEVERAL VIEWS OF THE DRAWINGS

FIG. 1A depicts an active tier assembly.

FIG. 1B depicts a portion of the active tier assembly of FIG. 1A.

FIG. 2 depicts a frame tier assembly.

FIG. 3 depicts the active tier assembled to the frame tier.

FIG. 4 depicts an under-fill applied to the frame and active tier assembly.

FIG. 5 depicts a heat spreader with BGA SAC balls attached.

FIG. 6A depicts a module sub-assembly including a thermal interface material.

FIG. 6B depicts a portion of the module sub-assembly including a thermal interface material of FIG. 6B.

FIG. 7 depicts the under-fill applied to the sub-assembly.

FIG. 8 depicts a top interface board with some memory device.

FIG. 9 depicts a lower-most or tier 0 module sub-assembly.

FIG. 10 depicts a final assembled module.

FIG. 11 is a set of process steps for a first embodiment of the invention.

FIG. 12 is a set of process steps for a second embodiment of the invention.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

Turning now to the figures wherein like references define like elements among the several views, Applicants disclose a method for the control of solder collapse in an electronic structure during solder reflow and a device made from the method.

Irvine Sensors Corporation, assignee of the instant application, has pioneered high density stacked multilayer microelectronic modules for use in a variety of applications.

The patents below disclose devices and methods wherein layers or tiers containing integrated circuit chips are stacked and electrically interconnected using any number of stacking techniques. For example, Irvine Sensors Corporation has developed several patented techniques for stacking and interconnecting multiple integrated circuits. Some of these techniques are disclosed in U.S. Pat. Nos. 4,525,921; 4,551,629; 4,646,128; 4,706,166; 5,104,820; 5,347,428; 5,432,729; 5,688,721; 5,953,588; 6,117,704; 6,560,109; 6,706,971; 6,717,061; 6,734,370; 6,806,559, 7,919,844, 7,768,113 and U.S. Pub. No. 2006/0087883.

Applicants have observed that solder failure may occur resulting from solder balls “collapsing” between layers or components in a microelectronic module during the solder reflow steps in module fabrication. The aforementioned failure mode is of particular concern when module processing involves multiple solder reflow steps or when larger component structures or multiple layers are involved. That is, individual solder balls between layers tend to collapse during one or more solder reflow processing steps due to the increased weight of the components or layers involved.

In order to minimize the number of reflow steps that active microelectronic components see during the assembly process (which can have an adverse effect on the reliability of the component) and, in order to minimize or eliminate the collapse of the BGA solder balls between the tiers in a multilayer microelectronic module or between a component and a bond pad, the process of the invention takes advantage of different melting points (also referred to herein as solder reflow temperatures) and material compatibility of different solder materials.

The preferred embodiment of the invention uses lead-free BGA elements comprising an Sn—Ag—Cu solder ball material (also referred to as “SAC” herein) as spacer elements and a solder paste such as an Sn63 solder paste as a solder material to minimize solder BGA collapse during fabrication.

During pre-assembly of a multilayer module, SAC BGA's are applied at predetermined bond pad locations on a printed circuit board, electrical component or predetermined location on one or more of the tiers or layers in the module to maximize yields by minimizing solder collapse in the final assembly.

This invention addresses the solder collapsing problem by minimizing the total number of solder reflows while preventing collapse by taking advantage of melting temperature differences between two compatible solder materials, which, in the illustrated embodiment uses an Sn63 solder paste and spacer elements such as SAC solder balls (tin, silver and copper).

The collapse is prevented by using Sn63 paste or equivalent material having a first lower reflow temperature which, for Sn63 is about 183C and a second solder element acting as a spacer element or shim having a second higher reflow temperature which, in the case of SAC solder balls, is about 217C.

A preferred embodiment of the method of the invention is discussed below.

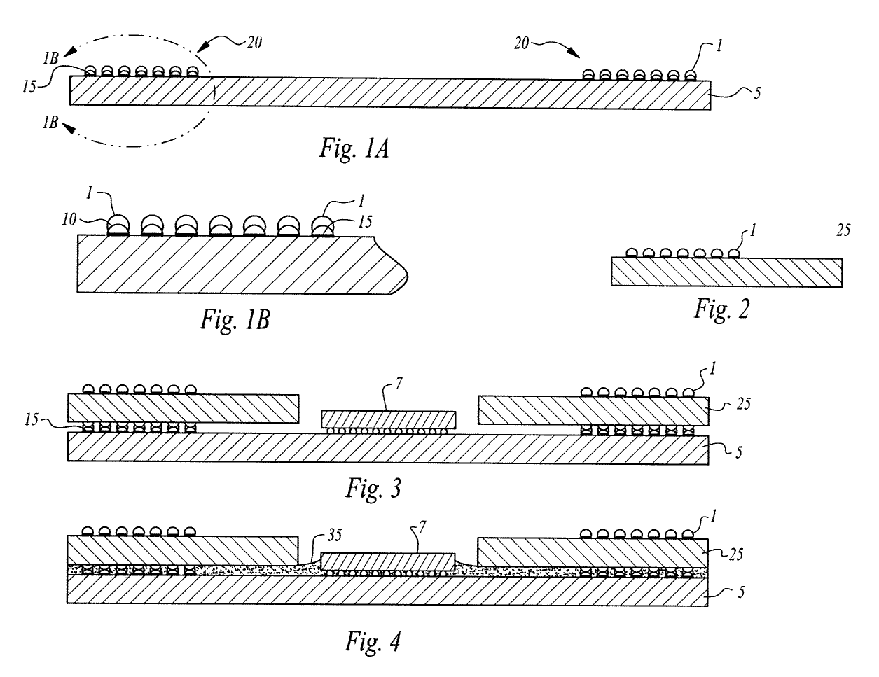

Turning to FIGS. 1A and 1B, it can be seen that during the sub-assembly, the SAC balls acting as spacer elements having a second higher reflow temperature 1 may be applied to active tier 5 at predetermined locations such as electrically conductive bond or contact pad locations 10 at about the same point in the assembly process that the active electronic components 7 are applied.

This may be achieved by first applying Sn63 solder paste having a first lower reflow temperature 15 on active tier 5 through vertical interconnect access (via) contacts or on the pads where active components are applied or both. Active components 7 may be placed by aligning their contact bumps with the active tier contact pads 10 where Sn63 paste 15 is applied. Next, spacer elements 1, which in the illustrated embodiment comprise SAC solder balls having about a 12 mil diameter, are placed on active tier 5 at predetermined locations such as the illustrated contact pads 10 on which Sn63 solder paste 15 was previously applied. The diameter of spacer element 1 may be any user defined diameter.

It is further noted spacer element 1 materials are not limited to SAC solder balls but may comprise any material and geometry that is suitable for use with the selected solder paste 15, here Sn63, and that has compatible electrical, chemical and physical characteristics.

In an alternative embodiment, spacer element 1 may comprise one or more stud bumps or stack of stud bumps applied using a conventional wire bond machine such as is available from West Bond, Inc. If stud bumps are used as spacer elements 1, the wire bond equipment should be capable of generating a uniform stud bump height, especially in instances where a stack of stud bumps is used.

The average height of stud bump formed with 2-mil Au wire is about 80 um in height. Since a two-mil wire is usually the maximum size that wire bonders can run, the stud bumping operation should be monitored to observe the overall stud bump height tolerances which may quickly change from stack to stack due to compression forces and stack tilt.

The sub-assembly is reflowed at the first lower temperature which, in the case of Sn63 solder paste is about 183C. This step secures the SAC balls spacer elements 1 to active tier 5 on the periphery as well as active components 7 upon active tier 5. This and subsequent reflow processes are all performed at a the first lower reflow temperature, in this case the Sn63 solder paste reflow temperature, which is below the second higher reflow temperature of SAC solder balls.

Turning now to FIG. 2, SAC ball spacer elements 1 are assembled to frame tier 25. For frame tiers 25, the SAC balls may be soldered directly to the frame tiers or a Sn63 solder paste used to attach the SAC balls. This serves to minimize the movement of the SAC balls during the sub-assembly process of attaching an active tier 5 to a frame tier 25.

The illustrated frame tier 25 of FIG. 2, which may comprise a through-via (not shown), may be used to frame active components 7 and to obtain continuity of the peripheral contacts from the sub-assembled active tier 5 below to the sub-assembled active tier above it. The SAC solder balls may be secured to frame tier 25 through via contacts in a manner similar to that used for the active tier 5.

At this point in the assembly process of the module, Sn63 paste 15 is applied on contact or bond pads 10 at predetermined locations followed by placement of the SAC solder balls as spacer elements 1 on top of the Sn63 paste 15. The Sn63 solder paste 15 is then reflowed at the first lower reflow temperature to ensure the SAC solder ball spacer elements 1 stay in place during the fabrication process of attaching a frame tier 25 to an active tier 5.

Turning now to FIG. 3, each active tier 5 is assembled to a frame tier 25 to form an intermediate assembly. This may be achieved by applying Sn63 solder paste 15 to the underside (opposite where SAC balls were placed) of frame tier 25. The tiers are then joined, by aligning and placing the frame tier onto active tier. Reflow at the first lower temperature is performed to effect assembly.

In FIG. 4, the frame tier/active tier assembly is then under filled using an under fill material 35 such as Hysol under fill available from Henkel Corp. The tiers may utilize Sn63 paste to bond to each other.

The space between the two tiers is filled with a suitable compound in an “under filling” process and the assembly under filled to bond and lock the tiers together.

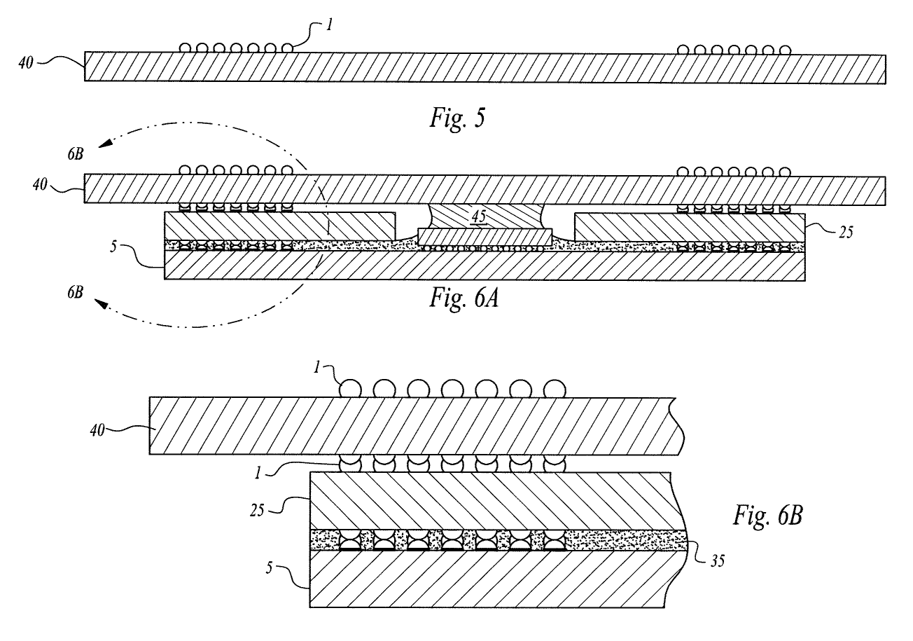

This sub-assembly is now ready for stacking although in large systems a heat spreader may be incorporated into the final assembly as illustrated in FIGS. 5-10.

As better seen in FIG. 5, the spacer element SAC balls 1 are attached to heat spreader elements 40 such as copper layers used for heat dissipation similar to that of the frame tiers 25 prior to being assembled to the active tier/frame tier assembly.

In the illustrated example, heat spreaders 40 are incorporated because the mass of the final system is large and there is a need to dissipate heat during system operation. The illustrated heat spreaders 40 may have insulated through vias. Sn63 solder paste 15 is applied on the vias and SAC solder balls spacer elements 1 applied thereto. Finally, a reflow operation at the first lower reflow temperature is conducted to secure the SAC balls to the heat spreader 40.

In a preferred embodiment of the module of the invention, heat spreader 40 may comprise a heat spreader such as is disclosed in pending U.S. application Ser. No. 12/925,147, entitled, “Thermal Management Device Comprising Thermally Conductive Heat Spreader With Electrically Isolated Through Hole Vias”, filed Oct. 13, 2010, the entirety of which is incorporated herein by reference.

Turning now to FIGS. 6A and 6B, heat spreader 40 is assembled to the active tier/frame tier assembly using Sn63 solder paste. The Sn63 solder paste is applied at predetermined locations such as to predefined underside contacts of the heat spreader 40. Heat spreader 40 may then be aligned and attached to the sub-assembly using a thermally conductive adhesive. Heat is applied to reflow the Sn63 solder paste and to simultaneously cure the adhesive.

A re-under fill operation is performed to fill the space between heat spreader 40 and the sub-assembly.

A thermal interface material 40 such as a thermally conductive paste may be applied during the assembly step of the heat spreader 40 to the active tier/frame tier assembly. This insures an efficient thermal path between the components 7, here comprising at least on field programmable gate array device or FPGA, and heat spreader 40.

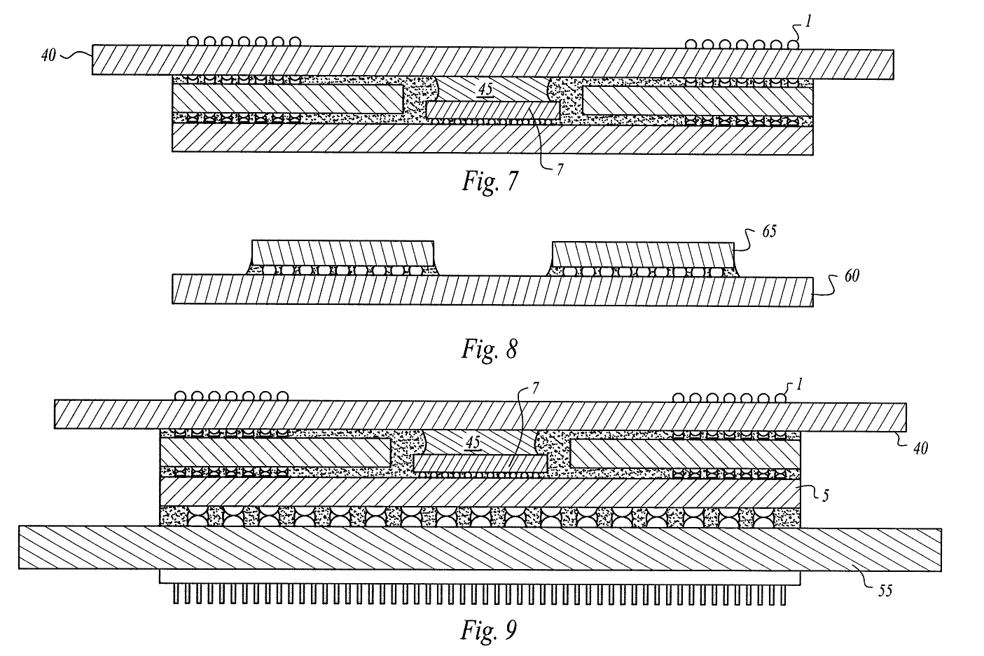

Once this module sub-assembly is completed, it is under filled between heat spreader 40 and the active tier/frame tier assembly as illustrated in FIG. 7. At this point in the process, one or more completed sub-assemblies are ready for stacking where plurality of sub-assemblies may be stacked into a final assembly.

The Sn63 solder paste is applied at predetermined locations such as on the electrical bond contacts between the sub-assemblies to be stacked.

Turning now to FIGS. 8, 9 and 10, the illustrated tier 0 module sub-assembly is bonded to the seal board 55 using Sn63 paste and SAC BGA balls as spacer elements 1. The spacer elements 1 may be pre-attached to the seal board 55 and attached to the tier 0 module sub-assembly as depicted in FIG. 9.

In certain applications, a top interface board 60 with external memory 65 may be used as depicted in FIG. 8.

The assembled top interface board 60 may then be assembled to the illustrated tier 3 module sub-assembly using Sn63 solder paste.

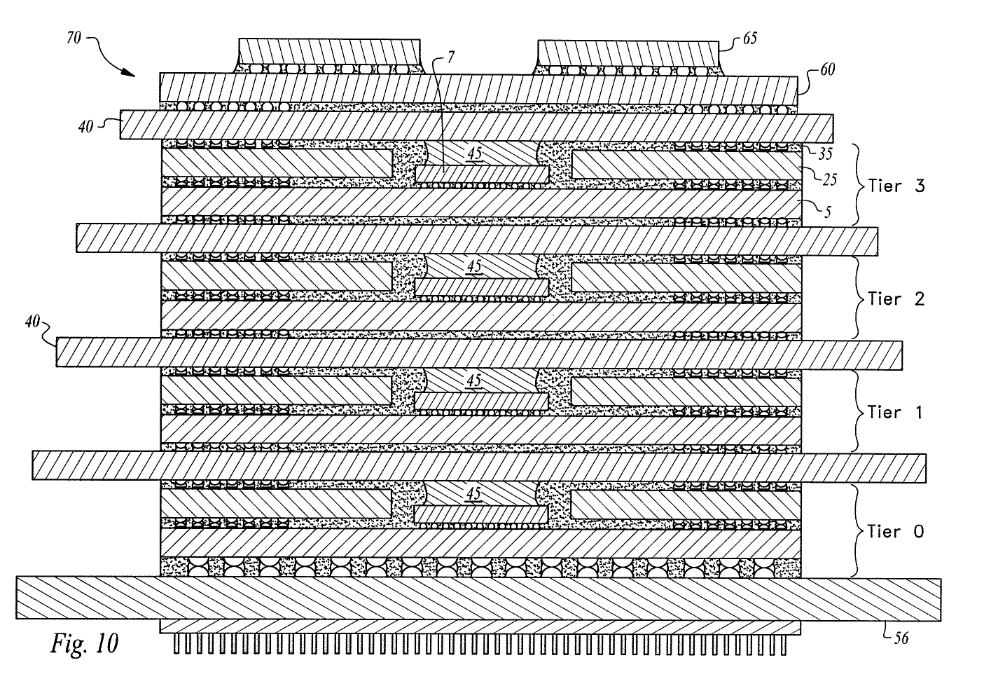

This is subsequently under-filled as seen in FIG. 10.

The entire final assembly 70 may then reflowed in a single operation at the first lower reflow temperature once tiers 0-3 are aligned and in place. Due to the fact the remaining assembly interfaces are off of the heat spreaders 40, the thermal transfer to the solder interfaces is less restrictive, efficiently permitting reflow at the lower final reflow temperature of the final assembly 70.

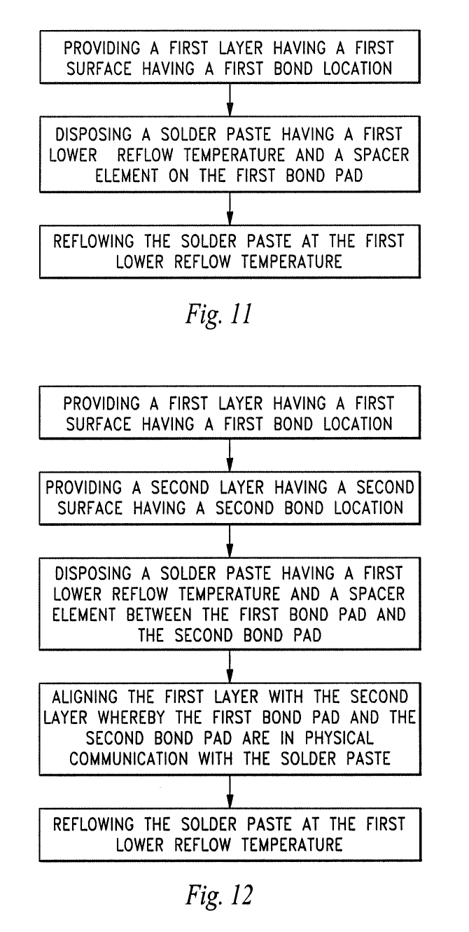

Turning now to FIG. 11, it can be seen that a process is provided to minimize solder collapse during solder reflow comprising the steps of providing a first layer having a first surface having first bond location disposed on it, disposing a solder paste having a first lower reflow temperature and a spacer element on the first bond pad and reflowing the solder paste at the first lower reflow temperature which is lower than the second higher reflow temperature of the space element wherein the spacer element does not reflow.

Turning now to FIG. 12, it can be seen that a process is provided to minimize solder collapse during reflow comprising the steps of providing a first layer having a first surface having first bond location disposed thereon, providing a second layer having a second surface having a second bond location disposed thereon, disposing a solder paste having a first lower reflow temperature and a spacer element between the first bond pad and the second bond pad, aligning the first layer with the second layer whereby the first bond pad and the second bond pad are in physical communication with the solder paste and, reflowing the solder paste at the first lower reflow temperature which is lower than the second higher reflow temperature of the space element wherein the spacer element does not reflow.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

We claim:

1. A process for reflow solder assembly of an electronic device comprising the steps of:
providing a first layer having a first surface having first bond location disposed thereon,
disposing a solder paste having a first lower reflow temperature and a spacer element on the first bond pad, and,
reflowing the solder paste at the first lower reflow temperature.

2. The process of claim 1 wherein the spacer element is an SAC solder ball having a predetermined geometry.

3. The process of claim 1 wherein the spacer element has a higher reflow temperature than the solder paste to define a second higher reflow temperature.

4. The process of claim 1 wherein the spacer element is comprised of at least one stud bump defined by a wire bond machine.

5. A process for reflow solder assembly of an electronic device comprising the steps of:
providing a first layer having a first surface having first bond location disposed thereon,
providing a second layer having a second surface having a second bond location disposed thereon,
disposing a solder paste having a first lower reflow temperature and a spacer element between the first bond pad and the second bond pad,
aligning the first layer with the second layer whereby the first bond pad and the second bond pad are in physical communication with the solder paste, and,
reflowing the solder paste at the first lower reflow temperature.

6. The process of claim 5 wherein the spacer element is an SAC solder ball having a predetermined geometry.

7. The process of claim 5 wherein the spacer element has a higher reflow temperature than the solder paste to define a second higher reflow temperature.

8. The process of claim 5 wherein the spacer element defines a predetermined distance between the first bond pad and the second bond pad.

9. The process of claim 5 wherein the spacer element comprise at least one stud bump defined by a wire bond machine.

10. An electronic module prepared by a process comprising the steps of:
providing a first layer having a first surface having first bond location disposed thereon,
providing a second layer having a second surface having a second bond location disposed thereon,
disposing a solder paste having a first lower reflow temperature and a spacer element between the first bond pad and the second bond pad,
aligning the first layer with the second layer whereby the first bond pad and the second bond pad are in physical communication with the solder paste, and,
reflowing the solder paste at the first lower reflow temperature.

11. The module of claim 10 wherein the spacer element is an SAC solder ball having a predetermined geometry.

12. The module of claim 10 wherein the spacer element has a higher reflow temperature than the solder paste to define a second higher reflow temperature.

13. The module of claim 10 wherein the spacer element defines a predetermined distance between the first bond pad and the second bond pad.

14. The module of claim 10 wherein the spacer element comprise at least one stud bump defined by a wire bond machine.
